(19) United States
(12) Patent Application Publication
(10) Pub. No.: US 2015/0114297 A1
(43) Pub. Date: Apr. 30, 2015

(54) VAPOR DEPOSITION DEVICE

(71) Applicant: Sharp Kabushiki Kaisha, Osaka (JP)

(72) Inventors: Shinichi Kawato, Osaka (JP); Katsuhiro Kikuchi, Osaka (JP); Manabu Niboshi, Osaka (JP); Takashi Ochi, Osaka (JP); Yuto Tsukamoto, Osaka (JP); Tomohiro Kosaka, Osaka (JP); Tomofumi Osaki, Osaka (JP)

(73) Assignee: Sharp Kabushiki Kaisha, Osaka (JP)

(21) Appl. No.: 14/406,042

(22) PCT Filed: Apr. 18, 2013
(86) PCT No.: PCT/JP2013/061547

§ 371 Date: Dec. 5, 2014

(30) Foreign Application Priority Data
Jun. 8, 2012 (JP) 2012-131402

(51) Int. Cl. C23C 14/24; C23C 14/50; C23C 14/04

(52) U.S. Cl. CPC C23C 14/243; C23C 14/042; C23C 14/50
USPC 118/726

(57) ABSTRACT

In a deposition device, a deposition mask of a mask unit (54) has a width in the scanning (movement) direction thereof that is less than a width of a target substrate (on which film will be deposited) in the same scanning direction. A substrate holder includes a substrate holding surface that has at least one curve along the scanning direction matching a bend in the target substrate caused by the weight thereof, and this curve occurs in the direction perpendicular to the scanning direction.

### TECHNICAL FIELD

The present invention relates to an evaporation apparatus that performs deposition using a deposition mask of which at least one side thereof is smaller than the substrate on which the film is formed (i.e., the target substrate).

### BACKGROUND ART

In recent years, flat-panel displays have been used in various products and fields, and there is demand for the flat-panel displays to be larger, to have higher resolution, and to consume less power.

Organic EL display devices having organic EL elements that use electroluminescence (hereinafter, “EL”) from organic materials have attracted heightened attention in this regard, due to being completely solid-state, having excellent low-voltage driving, fast response speed, emitting light on its own, and other advantages.

An organic EL display device has organic elements that are connected to TFTs (thin film transistors) and arranged on a substrate that is constituted of a glass substrate or the like, for example.

The organic EL elements are light-emitting elements that can emit high luminance light with low-voltage direct currents, and have a structure in which a first electrode, organic EL layers, and a second electrode are stacked in this order. The first electrode of the organic EL element is connected to the TFTs. A hole injection layer, hole transport layer, electron blocking layer, light emitting layer, hole blocking layer, electron transport layer, electron injection layer, or the like are stacked as the organic EL layers between the first electrode and the second electrode.

A full-color organic EL display device generally has sub-pixels of red (R), green (G), and blue (B) organic EL elements arrayed on a substrate, and the TFTs are used to selectively cause these organic EL elements to emit light at a desired brightness in order to perform image display.

The organic EL elements in the light-emitting section of this type of organic EL display device are generally formed by the layered deposition of organic films. During manufacturing of the organic EL display device, a light-emitting layer made of an organic light-emitting material that emits at least one of the colors above is deposited in a prescribed pattern on each organic EL element, which is a light-emitting element.

For deposition of the prescribed patterns, it is possible to use a vapor deposition method using a deposition mask called a shadow mask, ink-jet printing, laser transcription, or the like, for example. Currently, it is most common to perform deposition through vacuum evaporation with a deposition mask.

If the deposition mask is the same size as the substrate, however, then a larger substrate size will lead to a larger deposition mask.

This results in warping of the deposition mask due to the weight thereof and stretching, and causes gaps to appear between the substrate on which the film will be deposited and the deposition mask. As a result, it is not possible to form a pattern with high placement accuracy, which causes deviations in deposition positioning and mixed colors. This makes achieving a higher resolution difficult.

Furthermore, as substrate sizes become larger, so have the mask frames that hold the deposition mask and the substrate, leading to a substantial increase in weight. Due to this, not only have the devices for handling these types of deposition masks become much larger, more complicated, and difficult to design, but safety issues in regards to handling these devices occur in the manufacturing process, the process of changing the masks, and the like.

As a countermeasure, in recent years a method has been proposed in which a deposition mask smaller than the substrate on which the film is to be formed is used, and the deposition mask is moved relative to this target substrate (see Patent Documents 1 and 2, for example).

FIG. 11 is a perspective view of a schematic configuration of main parts of an evaporation apparatus 300 in Patent Document 1.

As shown in FIG. 11, the evaporation apparatus 300 in Patent Document 1 includes a patterning slit sheet 303 as the deposition mask, which is smaller than the substrate on which the film will be formed (the target substrate) 200. The evaporation apparatus 300 described in Patent Document 1 has a thin film deposition assembly 310 in which an evaporation source 302 having nozzles 301 is connected to a frame 304 that holds the patterning slit sheet 303 by a connector 305, and the substrate on which the film will be formed 200 is moved relative to the thin film deposition assembly 310 in order to perform scanning deposition using a scanning mode.

### RELATED ART DOCUMENTS

### Patent Documents

Patent Document 1: Japanese Patent Application Laid-Open Publication, “Japanese Patent Application Laid-Open Publication No. 2011-047048 (Published on Mar. 10, 2011)”

Patent Document 2: Japanese Patent Application Laid-Open Publication, “Japanese Patent Application Laid-Open Publication No. 2010-270394 (Published on Dec. 2, 2010)”

### SUMMARY OF THE INVENTION

### Problems to be Solved by the Invention

It is possible to solve the above-mentioned problems peculiar to such a large-sized deposition mask by using a deposition mask that is smaller than the target substrate (the substrate on which the film is formed) to deposit vapor particles on the target substrate through this deposition mask by the scanning of the target substrate or the mask unit (the evaporation source and the deposition mask). With this method, the problem of defects or the like caused by mutual contact can also be solved by the deposition mask and the target substrate being separated from each other.

This method, however, makes it difficult to ensure the flatness of the target substrate and the deposition mask, and there is a risk that the controllability of the gap between the target substrate and the deposition mask could worsen, and that positional deviations of the patterns could occur.

This is because the target substrate is still large even if the deposition mask has been made smaller, which makes it impossible to avoid distortions of the target substrate caused by the weight thereof. When the target substrate is large, the effects of these distortions caused by the weight thereof become markedly significant.

An electrostatic chuck is effective in preventing the target substrate from becoming distorted due to the weight thereof. As shown in FIG. 11, in Patent Document 1, a substrate holder 320 that functions as an electrostatic chuck has a holding surface that holds the target substrate 200. This prevents the target substrate 200 from bending due to the weight thereof, and keeps the target substrate 200 horizontal, thereby maintaining a uniform gap between the target substrate 200 and the patterning slit sheet 303.

When using a large-sized target substrate, however, it is necessary for the electrostatic chuck to be considerably durable to withstand the gravity (weight) of the target substrate. Therefore, this increases overall costs, and a large-sized electrostatic chuck would significantly burden the evaporation apparatus mechanism and impact the costs of the device. The effects of positional deviation and warping of the target substrate when being held by the electrostatic chuck will also be exacerbated by the target substrate being held horizontally (flat) against the gravity thereof. Thus, this causes a decrease in productivity due to a drop in deposition accuracy or, at worst, the breaking of the target substrate, or the like.

The present invention was made in view of the above-mentioned problems, and aims at providing an evaporation apparatus that can reduce stress and warping of the target substrate (the substrate on which the film is formed), stably hold the target substrate during scanning-mode deposition, and maintain a uniform gap between the target substrate and the deposition mask in the scanning direction.

### Means for Solving the Problems

To solve the above-mentioned problems, one aspect of the present invention includes an evaporation apparatus for forming a thin film having prescribed patterns on a substrate, the evaporation apparatus including: a mask unit including a deposition mask that has at least one opening and faces the substrate, and an evaporation source, the mask unit being secured in a position relative to the deposition mask; a substrate holder for holding the substrate at a gap from the deposition mask; and a moving mechanism that moves one of the a mask unit and the substrate relative to the other of the a mask unit and the substrate, wherein a width of the deposition mask in a scanning direction of the moving mechanism is less than a width of the substrate in the scanning direction, and wherein a substrate holding surface of the substrate holder has at least one curved portion along the scanning direction, the curved portion being within a range of a bend in the substrate caused by a weight thereof and curving in a direction perpendicular to the scanning direction of the moving mechanism.

### Effects of the Invention

As described above, in the evaporation apparatus according to one aspect of the present invention, the substrate holding surface of the substrate holder is curved to match the bend in the target substrate caused by the weight thereof, and thus it is not necessary to hold the target substrate horizontally against the weight thereof. This makes it possible to reduce stress or warping of the target substrate and to stably hold the target substrate, which can lead to an improvement in vapor deposition accuracy. Furthermore, the risk of damage to the target substrate itself is reduced, which allows for an improvement in yield and productivity. The costs of the device can also be reduced.

The curve of the substrate holder is curved in the direction perpendicular to the scanning direction along the scanning direction, and the substrate holding surface of the substrate holder is uniformly maintained in this curved shape along the scanning direction by scanning along the axis direction of the curve. Therefore, the gap between the target substrate and the deposition mask can be uniformly maintained along the scanning direction during scanning.

### BRIEF DESCRIPTION OF THE DRAWINGS

FIG. 1 is a cross-sectional view of a schematic configuration of main parts of an evaporation apparatus according to Embodiment 1.

FIG. 2 is another cross-sectional view of a schematic configuration of main parts of the evaporation apparatus according to Embodiment 1.

FIG. 3 is an overhead view of the primary constituting elements in a vacuum chamber in the evaporation apparatus according to Embodiment 1 when see diagonally from above.

FIG. 4 is a perspective view of a schematic configuration of a substrate mounting table of the deposition device according to Embodiment 1.

FIGS. 5(a) to 5(c) are cross-sectional views showing the flow of a substrate delivery process in order.

FIG. 6 is a cross-sectional view of a schematic configuration of main parts of the evaporation apparatus according to a modification example of Embodiment 1.

FIG. 7 is a cross-sectional view that schematically shows an arrangement of various vapor deposition elements around a substrate holder of an evaporation apparatus according to Embodiment 2.

FIG. 8 is a plan view of an arrangement of a panel area of a target substrate in Embodiment 2.

FIG. 9 is a perspective view of a schematic configuration of a substrate mounting table of the deposition device according to Embodiment 2.

FIG. 10 is a cross-sectional view that schematically shows an arrangement of various vapor deposition elements around a substrate holder of an evaporation apparatus according to Embodiment 3.

FIG. 11 is a perspective view of a schematic configuration of main parts of an evaporation apparatus in Patent Document 1.

### DETAILED DESCRIPTION OF EMBODIMENTS

Below, embodiments of the present invention will be explained in detail.

### Embodiment 1

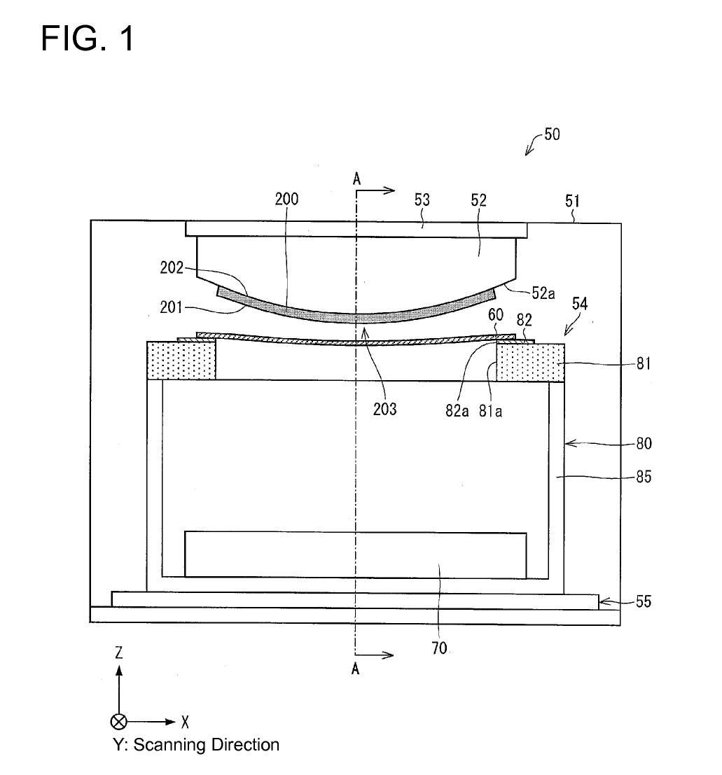

One embodiment of the present invention will be explained below with reference to FIGS. 1 to 6.

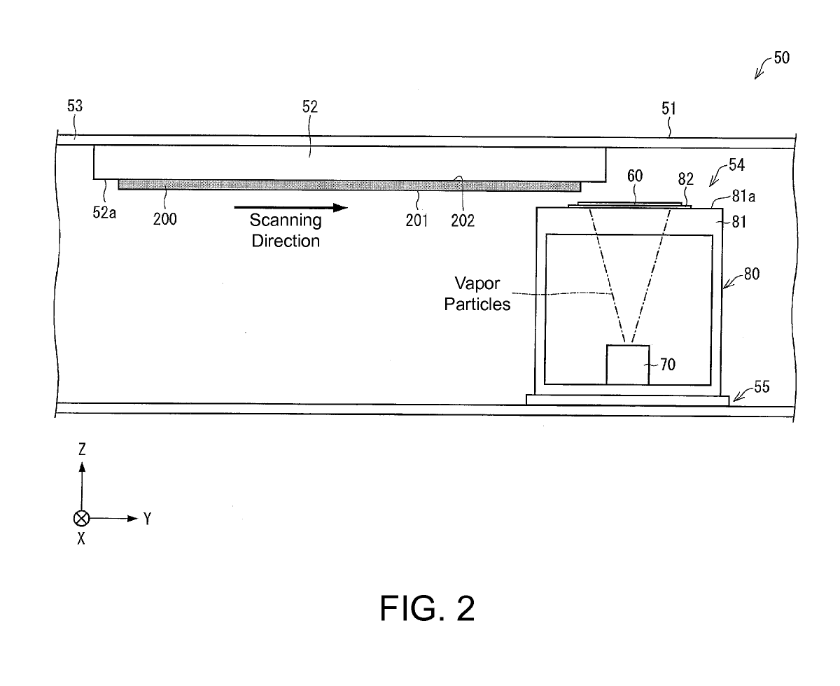

FIGS. 1 and 2 are both cross-sectional views of a schematic configuration of main parts of an evaporation apparatus according to Embodiment 1.

FIG. 1 shows a cross section of the evaporation apparatus of the present embodiment cut perpendicularly to the scanning direction (substrate scanning direction/first direction), and is equivalent to a cross-sectional view seen from a direction parallel to the scanning direction. Meanwhile, FIG. 2 shows a cross section of the evaporation apparatus of the present embodiment cut parallel to the scanning direction, and is equivalent to a cross-sectional view of the evaporation apparatus in FIG. 1 cut along the line A-A.

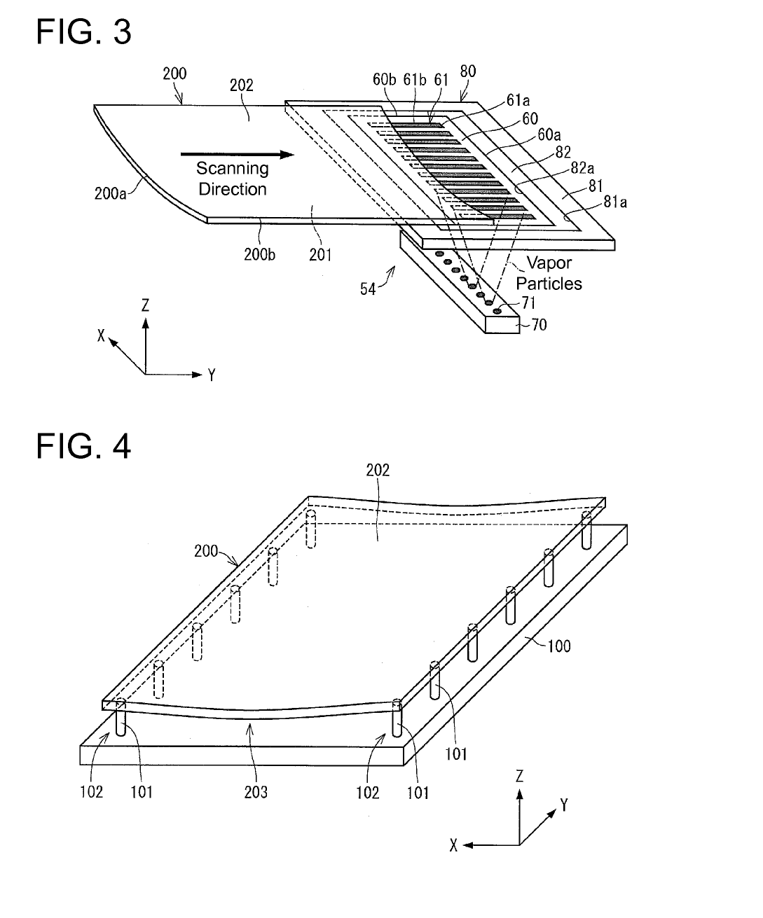

FIG. 3 is an overhead view of the primary constituting elements in a vacuum chamber in the evaporation apparatus according to the present embodiment when see diagonally from above.

The substrate holder is omitted in FIG. 3. In FIGS. 1 to 3, as an example, the scanning direction and the direction (first direction) parallel to the scanning direction are the Y direction (Y axis direction), and the direction (second direction) perpendicular to the scanning direction is the X direction (X axis direction).

<Entire Configuration of Evaporation Apparatus>

As shown in FIGS. 1 and 2, an evaporation apparatus 50 of the present embodiment includes: a vacuum chamber 51 (film deposition chamber); a substrate holder 52, which is a substrate holding member that holds a target substrate 200 (a substrate on which film will be deposited); a substrate moving mechanism 53 (moving mechanism) that moves the target substrate 200; a mask unit 54 (evaporation unit); a mask unit moving mechanism 55 (moving unit) that moves the mask unit 54; a substrate mounting table 100 that, before the target substrate 200 is held by the substrate holder 52, temporarily holds the target substrate 200 while the substrate 200 bends due to its own weight (target substrate holding member, see FIG. 4); an alignment monitoring unit such as an image sensor (not shown); a control circuit; and the like.

As shown in FIGS. 1 and 2, the substrate holder 52, the substrate moving mechanism 53, the mask unit 54, and the mask unit moving mechanism 55 are provided in the vacuum chamber 51.

The substrate mounting table 100 is provided in the vacuum chamber 51 in an area reachable by the substrate holder 52 so as to be separated from a deposition area of the mask unit 54.

In order to maintain a vacuum inside the vacuum chamber 51 during vapor deposition, a vacuum pump (not shown) that evacuates the inside of the vacuum chamber 51 is provided via an exhaust port (not shown) disposed in the vacuum chamber 51.

<Entire Configuration of Mask Unit>

As shown in FIGS. 1 to 3, the mask unit 54 includes a deposition mask 60 called a shadow mask, an evaporation source 70, a mask holding member 80, a shutter (not shown), and the like.

The mask holding member 80 includes a mask holder 81, a mask tray 82, and a mask holder securing member 85. The deposition mask 60 is placed on the mask tray 82 on the mask holder 81. The mask holder 81 holds the deposition mask 60 by holding the mask tray 82, which directly holds the deposition mask 60. The evaporation source 70 is disposed below the deposition mask 60.

The mask holder 81 is held and secured by the mask holder securing member 85. The shape of the mask holder securing member 85 has no particular limitations as long as the mask holder 81 can be held and secured at a uniform distance from the evaporation source 70.

The deposition mask 60 and the evaporation source 70 are integrally held by the mask holding member 80 and the positions thereof are secured relative to each other.

When moving the target substrate 200 relative to the mask unit 54, however, the deposition mask 60 and the evaporation source 70 do not necessarily need to be integrated, as long as the positions thereof are secured relative to each other. The relative positions of the deposition mask 60 and the evaporation source 70 may be secured by the evaporation source 70 and the mask holding member 80 each being secured to the inner wall of the vacuum chamber 51, for example.

The deposition mask 60 and the evaporation source 70 are arranged facing either other with a uniform gap therebetween so as to allow an empty area of uniform height to exist between the deposition mask 60 and the evaporation source 70. The empty area between the deposition mask 60 and the evaporation source 70 can be configured as desired and has no particular limitations. In order to increase the use efficiency of the deposition materials, however, it is preferable that the empty area be as small as possible, such as approximately 100 mm, for example.

<Deposition Mask>

A metal mask is preferably used as the deposition mask 60. The material of the deposition mask 60 can be similar to a conventional configuration having heat resistant characteristics.

The deposition mask 60 is smaller in size than the target substrate 200, and as shown in FIGS. 2 and 3, at least the width of the deposition mask 60 in the direction parallel to the scanning direction is less than the width of the target substrate 200 in the direction parallel to the scanning direction.

As shown in FIG. 2, in the present embodiment, the deposition mask 60 has a rectangular (belt-like) shape in which the width of a long side 60a thereof in the lengthwise direction perpendicular to the scanning direction is longer than the width of a short side 200a of the target substrate 200 parallel to the long side 60a. Furthermore, the width of a short side 60b of the deposition mask 60 perpendicular to the lengthwise direction thereof and parallel to the scanning direction is less than the width of a long side 200b of the target substrate 200 parallel to the short side 60b.

The orientation of the long side 200b of the target substrate 200 with respect to the deposition mask 60, however, is not limited to this, and the deposition mask 60 and the target substrate 200 may be arranged such that the long side 200b of the target substrate 200 is parallel to the long side 60a of the deposition mask 60, depending on the size of the target substrate 200.

As shown in FIG. 3, a plurality of belt-shaped (striped) openings 61 (through-holes) are arrayed in a one-dimensional direction on the deposition mask 60, for example.

The lengthwise direction of the openings 61 is parallel to the scanning direction, and a plurality of the openings are lined up next to each other along a direction perpendicular to the scanning direction. In the present embodiment, the openings 61, which extend in parallel to the short side 60b of the deposition mask 60, are arranged in a plurality along the lengthwise direction of the deposition mask 60.

The shape of the openings 61 in the deposition mask 60, however, is not limited to this, and when forming the vapor deposition film pattern for each of the pixels on the target substrate 200, a fine mask that has openings 61 corresponding to each pixel is used, for example. On the other hand, when forming the vapor deposition film pattern on the entire display area of the target substrate 200, an open mask that exposes the entire display area may be used.

Alignment markers (not shown) for aligning the target substrate 200 relative to the deposition mask 60 along the substrate scanning direction of the target substrate 200, or namely, along the long side 61b of the openings 61, are provided on the deposition mask 60, for example. Thus, in the present embodiment, the alignment markers (not shown) are provided along the short side 60b of the deposition mask 60. In the present embodiment, scanning (the movement of the target substrate 200 relative to the deposition mask 60) is performed along the long side 200b of the target substrate 200.

Meanwhile, alignment markers (not shown) for aligning the target substrate 200 relative to the deposition mask 60 are provided along the scanning direction of the target substrate 200 on the outside of the deposition area on the target substrate 200.

<Evaporation Source>

The evaporation source 70 is a container that houses the vapor deposition materials, for example. The evaporation source 70 may be a container that directly houses the vapor deposition materials, or may be a container that has a load lock pipe.

As shown in FIG. 3, the evaporation source 70 is formed in a rectangular (belt-like) shape, for example, in a manner similar to the deposition mask 60. The surface of the evaporation source 70 facing the deposition mask 60 has a plurality of emitting ports 71 that emit (scatter) the vapor deposition material as vapor particles.

As shown in FIG. 3, these emitting ports 71 are aligned along the arrangement direction of the openings 61 in the deposition mask 60.

The pitch of the emitting ports 71, however, does not need to match the pitch of the openings 61. The size of the emitting ports 71 also does not need to match the size of the openings 61.

As shown in FIG. 3, when the deposition mask 60 has the striped openings 61, the diameter of the emitting ports 71 can be either greater or less than the width of the short side 61a of the openings 61, for example.

Furthermore, a plurality of emitting ports 71 may be provided for each of the openings 61, or one of the emitting ports 71 may be provided for a plurality of the openings 61. Some (at least one) of the emitting ports 71 or some area of the emitting ports 71 may face the non-open portions (between the openings 61 and 61, for example) of the deposition mask 60.

In order to lower the amount of vapor particles that attach to the non-open portions of the deposition mask 60 and improve material use efficiency as much as possible, however, it is preferable that each of the emitting ports 71 face the respective openings 61 such that at least a portion of each of the emitting ports 71 overlaps one or a plurality of the openings 61.

It is even more preferable that each of the emitting ports 71 face the respective openings 61 such that each of the emitting ports 71 is positioned within the respective openings 61 in a plan view.

In order to improve material use efficiency, it is preferable that the openings 61 and the emitting ports 71 correspond to each other on a 1-to-1 basis (i.e., that one opening corresponds to one emitting port).

<Mask Holder and Mask Tray>

As shown in FIGS. 1 and 3, the mask holder 81 and the mask tray 82 that hold the deposition mask 60 have a frame shape in which the center thereof is opened.

An opening 82a is provided in a portion of the mask tray 82 directly facing the opening area of the deposition mask 60, and this opening area is constituted of a group of the openings 61. The mask tray 82 holds the deposition mask 60 at the outer edges thereof.

An opening 81a is provided in a portion of the mask holder 81 directly facing the opening area of the deposition mask 60, which is constituted of the group of the openings 61. The mask holder 81 holds the mask tray 82, on which the deposition mask 60 has been placed, at the outer edges thereof.

The evaporation source 70 is placed under the deposition mask 60 below the openings 81a and 82a. The vapor particles scattered from the evaporation source 70 are deposited on the target substrate 200 through the openings 61 in the deposition mask 60. This forms a vapor-deposited film on the film deposition area (vapor deposition area/panel area) of the target substrate 200 facing the deposition mask 60.

<Substrate Moving Mechanism 53 and Mask Unit Moving Mechanism 55>

The substrate moving mechanism 53 includes a motor (not shown). A motor driving control unit (not shown) drives the motor to move the target substrate 200 held by the substrate holder 52.

Meanwhile, the mask unit moving mechanism 55 includes a motor (not shown). A motor driving control unit (not shown) drives the motor to move the mask unit 54 relative to the target substrate 200 while the deposition mask 60 is held in a position relative to the evaporation source 70.

The substrate moving mechanism 53 and the mask unit moving mechanism 55 cause the respective motors (not shown) to be driven, and perform positional correction with the alignment markers such that positional deviations between the deposition mask 60 and the target substrate 200 are corrected.

The substrate moving mechanism 53 and the mask unit moving mechanism 55 may be a roller moving mechanism, or may be a hydraulic moving mechanism, for example.

The substrate moving mechanism 53 and the mask unit mechanism 55 each may include a driving unit constituted of a motor (XYθ driving motor) such as a stepping motor (pulse motor), rollers, gears, or the like, and a driving control unit such as a motor driving control unit. The driving control unit may drive the driving unit to move the target substrate 200 or the mask unit 54. The substrate moving mechanism 53 and the mask unit moving mechanism 55 may include a driving unit constituted of an XYZ stage or the like, which may move in the X direction, Y direction, and Z direction (Z axis direction).

At least one of the target substrate 200 and mask unit 54, however, may be capable of being moved relative to the other. In other words, at least one of the substrate moving mechanism 53 and the mask unit moving mechanism 55 may be provided.

If the target substrate 200 is capable of being moved, for example, the mask unit 54 may be secured to the inner wall of the vacuum chamber 51. Conversely, if the mask unit moving mechanism 55 is capable of being moved, the substrate holder 52 may be secured to the inner wall of the vacuum chamber 51.

<Substrate Holder>

As shown in FIGS. 1 and 2, the substrate holder 52 holds the target substrate 200, which is constituted of a TFT substrate or the like, such that a film deposition surface 201 thereof faces the deposition mask 60 on the mask unit 54.

The target substrate 200 and the deposition mask 60 face each other with a gap therebetween, and there is an empty area between the target substrate 200 and the deposition mask 60.

A substrate holding surface 52a of the substrate holder 52 has a shape that follows the bending of the target substrate 200 caused by the weight thereof.

As shown in FIG. 1, in the present embodiment, the substrate holding surface 52a of the substrate holder 52 is a curve that matches the bending of the target substrate caused by the weight thereof. When seen from the direction parallel to the scanning direction, the substrate holding surface 52a is curved downwards in a protruding shape, and as shown in FIG. 2, has a uniform lens shape (plano-convex lens shape) along the scanning direction. The target substrate 200 is adhered along the curved surface of the substrate holding surface 52a of the substrate holder 52.

In FIGS. 1 and 2, an example is shown in which the substrate holding surface 52a of the substrate holder 52 is larger than the target substrate 200, but the present embodiment is not limited to this. The substrate holding surface 52a of the substrate holder 52 should be capable of stably holding the target substrate 200 while the target substrate 200 is bent by the weight thereof, or while in a state approximate to this, such that an excessive amount of stress is not exerted on the target substrate 200.

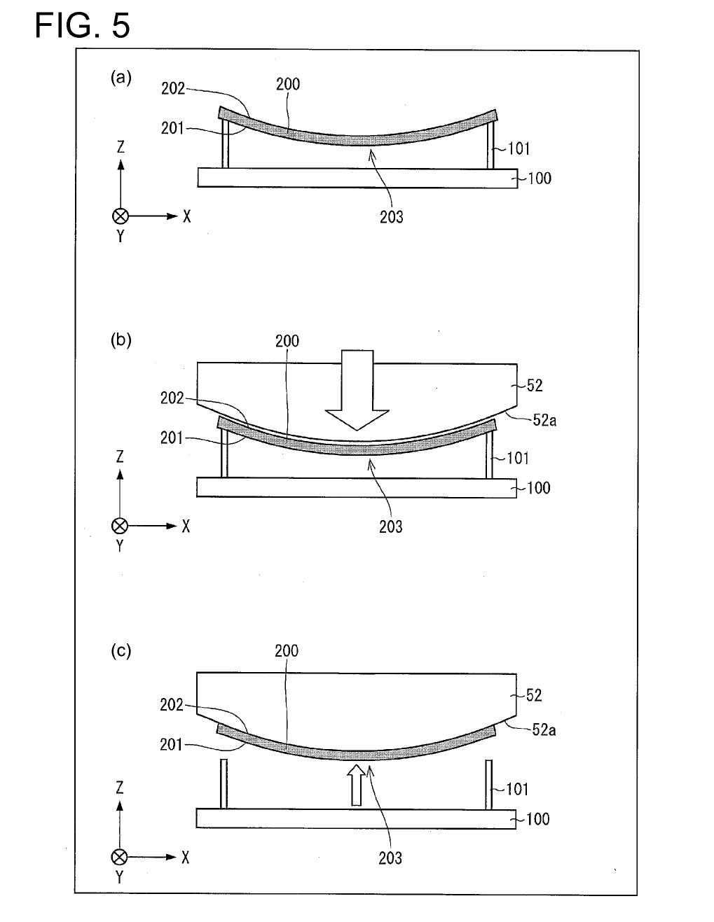

Therefore, the substrate holding surface 52a of the substrate holder 52 may be the same size as the target substrate 200 or slightly smaller than the target substrate 200, for example. It is preferable that the curvature of a protrusion 203 (see FIGS. 4 and 5(a) to 5(c)) of the target substrate 200 while placed on the substrate mounting table 100 be the same as the curvature of the substrate holding surface 52a of the substrate holder 52, but this is not strictly necessary. There is no problem with allowing the curvature of the substrate holding surface 52a to be determined by workability, accuracy, or other production factors, for example.

In the present embodiment, an electrostatic chuck is used for the substrate holder 52. In other words, the substrate holder 52 according to the present embodiment functions as an electrostatic chuck, and the target substrate 200 is adsorbingly held (secured) and adhered to the substrate holding surface 52a, which is a substrate adsorbing surface.

The material or the like of the substrate holder 52 has no particular limitations, and materials similar to those used in traditional substrate holders can be used. Using an electrostatic chuck for the substrate holder 52 and as a substrate holding unit is a well-known technique, as shown in Patent Document 1 and the like, for example, and conventional technology can be used for the electrostatic chuck mechanism itself.

The size (vertical distance) of the gap between the deposition mask 60 and the target substrate 200 in the direction perpendicular (Z direction) to the scanning direction changes due to the bending of the target substrate 200 by the weight thereof. Therefore, the gap between the deposition mask 60 and the target substrate 200 when overlapping is suitably determined by the size of the target substrate 200, the weight thereof, and the like. This gap has no particular limitations, but is preferably 50 μm to 1 mm, and even more preferably approximately 200 to 500 μm.

If the gap is less than 50 μm, there is an increased risk of the target substrate 200 contacting the deposition mask 60. On the other hand, if the height of the gap exceeds 1 mm, the vapor particles that pass through the openings 61 in the deposition mask 60 will spread out, and the pattern width of the vapor-deposited film will be too wide. If the vapor-deposited film is a red light-emitting layer used in an organic EL display device, for example, then the gap exceeding 1 mm creates a risk of the red light-emitting material being deposited in the adjacent green, blue, or other colored sub-pixels.

If the height of the gap is approximately 200 to 500 μm, then there is no risk of the target substrate 200 contacting the deposition mask 60, and it is possible to sufficiently minimize the pattern width of the vapor-deposited film being too wide.

Thus, it is preferable that the curvature of the substrate holder 52 be configured such that the gap between the deposition mask 60 and the target substrate 200 be within the appropriate range described above.

<Substrate Mounting Table 100>

FIG. 4 is a perspective view of a schematic configuration of the substrate mounting table 100.

As shown in FIG. 4, a plurality of pins 101 for mounting the target substrate 100 are provided on the substrate mounting table 100, which is used in the delivery of the target substrate 200. These pins 101 are arranged in two columns with gaps therebetween, and respective pin columns 102 constituted of the pins 101 have gaps therebetween corresponding to the length of the target substrate 200 in the direction perpendicular to the scanning direction, such that the respective pins 101 are arranged along both ends of the target substrate 200 parallel to the scanning direction.

Before the target substrate 200 is held by the substrate holder 52, the pins 101 temporarily hold the target substrate 200 while the target substrate 200 is bent due to the weight thereof, and in the substrate delivery process, the pins 101 are used for delivery of the target substrate 200 to the substrate holder 52.

In the present embodiment, an example is described in which the substrate mounting table 100, which has the pins 101, is provided as a target substrate holding unit in the vacuum chamber 51, but if the delivery of the target substrate 200 by the target substrate holding unit is being performed through elevation of the substrate holder 52, as described later, for example, then the pins 101 may be directly secured to the bottom wall of the vacuum chamber 51, for example.

The material, size, arrangement interval (pitch), and the like of the pins 101 have no particular limitations, as long as the pins 101 are selected/designed such that the target substrate 200 can be held while uniformly bending due to the weight thereof across the scanning direction, with the bottom of the target substrate 200 in the center of the direction parallel to the scanning direction. Essentially, the bending of the target substrate 200 due to the weight thereof should be able to correspond to the curved surface of the substrate holding surface 52a of the substrate holder 52.

<Substrate Delivery Process (Substrate Reception Process)>

Next, the substrate delivery process, in which the target substrate 200 is delivered to the substrate holder 52 from the substrate mounting table 100 by the target substrate 200 being adsorbed onto the substrate holder 52, will be described with reference to FIGS. 4 and 5(a) to 5(c) below.

FIGS. 5(a) to 5(c) are cross-sectional views showing the flow of the substrate delivery process in order.

In the substrate delivery process, first, as shown in FIGS. 4 and 5(a), an arm or other unit (not shown) transports the target substrate 200 to the top of the substrate mounting table 100. This places the target substrate 200 on the pins 101 such that the ends of the target substrate 200 parallel to the scanning direction are respectively positioned on top of the pins 101. At this time, in the present embodiment, the film deposition surface 201 of the target substrate 200 is placed so as to be positioned on the bottom (the side facing the pins 101).

Thus, the target substrate 200 is only supported by the pins 101 at both ends of the target substrate 200 parallel to the scanning direction, thereby allowing the center of the target substrate 200 perpendicular to the scanning direction to naturally bend along the direction parallel to the scanning direction. This forms the downward protrusion 203 (curved surface) on the target substrate 200 along the direction perpendicular to the scanning direction. In other words, by arranging the pins 101 as described above, the target substrate 200 will have a substantially uniform bend across the scanning direction.

Next, as shown in FIG. 5(b), a substrate holder elevation mechanism lowers the substrate holder 52 until the substrate holding surface 52a is slightly in contact with the target substrate 200.

The substrate holder elevation mechanism has no particular limitations as long as the substrate holder 52 can be moved up and down, and the substrate moving mechanism 53 may double as the substrate holder elevation mechanism by using an XYZ stage or the like with the substrate moving mechanism 53, for example, or the substrate holder elevation mechanism may be provided separately from the substrate moving mechanism 53. An actuator having an adsorbing mechanism, or raising and lowering of the substrate holder 52 using wires connected to the substrate holder 52 can be used as this type of substrate holder elevation mechanism, for example.

In FIG. 5(b), the substrate holder 52 is lowered until slight contact is made with the target substrate 200, but the pins 101 may also function to rise towards the substrate holder 52 until the target substrate 200 is slightly contacting the substrate holder 52. In this case, the pins 101 may be formed on an operating table attached to an actuator, for example, or the pins 101 themselves may be formed by an actuator.

Next, as shown in FIG. 5(c), the electrostatic chuck mechanism installed in the substrate holder 52 is turned ON, thereby adsorbing a non-film deposition surface 202 of the target substrate 200, which is opposite to the film deposition surface 201 and not modified by the vapor deposition process, to the substrate holder 52.

This causes the non-film deposition surface 202 of the target substrate 200 to be adsorbingly held (secured) and adhered to the substrate holding surface 52a of the substrate holder 52.

As shown in FIGS. 5(b) and 5(c), due to the curve of the substrate holding surface 52a of the substrate holder 52 having approximately the same curvature as the bend of the target substrate 200 due to the weight thereof, the target substrate 200 barely moves, even when the electrostatic chuck is turned ON, and the target substrate 200 itself is adsorbed to the substrate holder 52 without stress or warping.

The electrostatic chuck mechanism is installed inside the substrate holder 52 along with a battery or the like, for example.

<Vapor Deposition Process>

The target substrate 200 that has been adsorbed onto the substrate holder 52 in this manner is subjected to a deposition treatment to deposit a film thereon through vacuum deposition. As described above, examples of this deposited film include organic layers such as light-emitting layers of various colors or electrodes and the like for an organic EL display device.

In the vapor deposition process, the vapor particles that have been emitted from the evaporation source 70 are deposited onto the target substrate 200 through the openings in the deposition mask 60 while the target substrate is scanned along the axis direction of the curved surface of the substrate holder 52. As shown in FIGS. 1 and 3, for example, when seen from a direction parallel to the scanning direction, vapor deposition (scanning deposition) is performed by the target substrate 200 being moved relative to the mask unit 54 while the target substrate 200 is held so as to have a downward-protruding curved surface.

At this time, as shown in FIG. 3, the deposition mask 60 is held by the mask holder 81 such that the scanning direction matches the long axis direction (lengthwise direction) of the striped openings in the deposition mask 60.

In the example shown in FIGS. 1 to 3, the target substrate 200, which is a TFT substrate or the like, is held in a state in which the film deposition surface 201 thereof faces the mask surface, which is where the openings in the deposition mask 60 are formed. The target substrate 200 or the mask unit 54 is carried in this state in the Y axis direction in an XY plane, thereby causing the target substrate 200 to pass over the top of the deposition mask 60 and the evaporation source 70.

Due to this, in the present embodiment, the vapor particles are emitted upwards from below, and thus become deposited onto the film deposition surface 201 of the target substrate 200 through the openings 61 in the deposition mask 60 (up deposition).

The present invention, however, is not limited to this, and as shown in embodiments that are described later, the vapor particles may be deposited onto the film deposition surface 201 of the target substrate 200 by the target substrate 200 being disposed below the deposition mask 60 and the evaporation source 70 and the vapor particles being emitted downwards from the evaporation source 70 (down deposition).

<Effects>

According to the present embodiment, as described above, the substrate holding surface 52a of the substrate holder 52 is curved to match the bend of the target substrate 200 caused by the weight thereof, and the substrate holding surface 52a has a curved shape that follows the bending of the target substrate 200 caused by the weight thereof; therefore, when using the electrostatic chuck on the target substrate 200, the distance between the target substrate 200 and the substrate holding surface 52a of the target substrate 52 changes very little, and the electrostatic chuck can be used with ease.

Furthermore, the substrate holding surface 52a of the substrate holder 52 maintains a uniform curved shape (a lens shape in the present embodiment) along the scanning direction, and thus, while scanning is being performed, the distance between the target substrate 200 and the deposition mask 60 is uniformly maintained along the scanning direction.

The gap between the target substrate 200 and the deposition mask 60 along the direction perpendicular to the scanning direction is not uniform, but this does not pose a problem. If a prescribed gap is maintained between the target substrate 200 and the deposition mask 60 in the scanning direction, then the deposition mask 60 can be adjusted to match the design of the target substrate 200 by designing the size and shape of the openings 61 in the deposition mask 60 such that a film of a desired thickness is deposited in a desired area in accordance with this gap, for example. Changes during scanning or a deterioration in repeating accuracy pose more a problem than the above.

In the present embodiment, the substrate holding surface 52a, which is the surface of the substrate holder 52 in contact with the target substrate 200, has approximately the same (preferably, the exact same) shape as the bend of the target substrate 200 caused by the weight thereof before the electrostatic chuck is used, thereby allowing for the target substrate 200 to be adsorbed without exerting an excessive amount of stress on the target substrate 200.

In the present embodiment, for example, the substrate holding surface 52a of the substrate holder 52 has a lens shape, as described above, and the bending of the target substrate 200 caused by the weight thereof before the electrostatic chuck is used also has this type of shape, which is highly advantageous due to the target substrate 200 being able to be adsorbed without exerting stress on the target substrate 200.

Therefore, as described above, it is preferable that the target substrate 200 be adsorbed onto the substrate holder 52, which has a curved shape that is approximately the same (preferably exactly the same) shape as the curved surface of the target substrate 200, while the target substrate 200 is placed on the pins 101 and curved, as shown in FIG. 4, for example.

In this manner, the substrate holding surface 52a of the substrate holder 52 is curved beforehand in expectation of the bending of the target substrate 200 due to the weight thereof, thereby allowing for the target substrate 200 to be absorbed onto the substrate holder 52 with ease, even if a markedly durable large-sized electrostatic chuck that would be necessary for holding the target substrate 200 horizontal is not used. Therefore, the holding mechanism (adhering mechanism) of the target substrate 200 is simple and will not cause needless stress to be exerted on the substrate.

The arrangement of the substrate holding surface 52a of the substrate holder 52 and the pins 101 may be designed such that the substrate holding surface 52a has a curved shape that is approximately the same (preferably exactly the same) as the curved surface of the target substrate 200 when the target substrate 200 is mounted on the pins 101, and the position of the pins 101 may be determined such that the gap between the target substrate 200 and the deposition mask 60 is within a specific range, for example.

As described above, the target substrate 200 can be stably secured to the substrate holder 52 by forming a curve that follows the bending of the target substrate 200 due to the weight thereof on the substrate holding surface 52a of the substrate holder 52. This reduces stress and warping of the target substrate 200, and the target substrate will not vibrate or shake during the scanning thereof. Thus, it is possible to improve deposition accuracy and, due to the risk of damage to the target substrate 200 itself being reduced, possible to increase yield.

Accordingly, the present embodiment makes it possible to lower the costs of the device and improve productivity by stabilizing repeating accuracy and the like.

When the substrate holder 52 has an electrostatic chuck mechanism, in particular, it is possible to reduce the power of the electrostatic chuck, as described above, and to reduce the corresponding costs of the device.

Furthermore, the simplification of substrate adhering mechanisms such as the electrostatic chuck contributes to reducing the weight of the substrate holder 52. Therefore, this can also reduce the costs of the device. The effects are particularly marked when the substrate holder 52 is provided above the mask unit, as described above, or when the substrate holder 52 physically scans (moves).

Accordingly, if the substrate holder 52 is fabricated having a curve that corresponds to the target substrate 200, which is significantly affected by bending due to the weight thereof, and can withstand the weight thereof, and if the substrate holder 52 also has the electrostatic chuck mechanism as described above, then the controllability of the gap (gap control) between the target substrate 200 and the deposition mask 60 will be stable.

In the present embodiment, there are no particular limitations to the size of the target substrate 200, but greater effects are exhibited with G6 (1500 mm×1800 mm, for example) ultra-large substrates and above, and thin substrates with a thickness of 1.0 mm or less, in particular.

Furthermore, according to the present embodiment, it is possible to reduce the power of the electrostatic chuck as described above; therefore, it is possible to reduce the charge of the target substrate 200, which allows for the smooth removal of the target substrate 200 when the electrostatic chuck is turned OFF.

By reducing the power of the electrostatic chuck, it is possible to reduce the effect on the TFTs or the damage thereof when the target substrate 200 is a TFT substrate, for example.

### Modification Example

If the above-mentioned effects can be achieved, there are no particular limitations to the mechanism or shape of the respective parts of the evaporation apparatus 50 and the configurations beside the substrate holder 52, in particular. There are also no particular limitations to the structure of the evaporation source 70, the structure of the entire deposition device 50, and the like, for example. A modification example of the deposition device 50 will be described below.

(Substrate Mounting Table 100)

In FIG. 4, an example was described in which the pins 101 were provided on the substrate mounting table 100 as support members that support the target substrate 200. To achieve the above-mentioned effects, however, it is clear that the support members do not necessarily need to be pin shaped. Bar-shaped support members may be used instead of the pins 101 or the pin columns 102, and the target substrate 200 may be supported by a hanger or the like being suspended from above, instead of the target substrate 200 being supported from below, for example. The target substrate 200 may also be supported from the sides by arm-shaped support members.

The mounting table 100 itself does not necessarily need to have the plate shape shown in FIG. 4. If using arm-shaped support members that support the target substrate 200 from the sides, instead of the pins 101 that support the target substrate 200 from below as described above, then the plate-shaped substrate mounting table 100 (support table, plate-shaped member) shown in FIG. 4 is not provided, for example. In this case, a plurality of hanger members can be used instead of the support table described above, for example. In a similar manner, a support table or the like such as that shown in FIG. 4 is not necessary if suspending the target substrate 200 from above with a hanger-shaped support member.

In any case, the pins 101 and bar, arm, hanger, or miscellaneously-shaped support member may be directly provided in the vacuum chamber 51 without the support table or the like.

(Mask Unit 54)

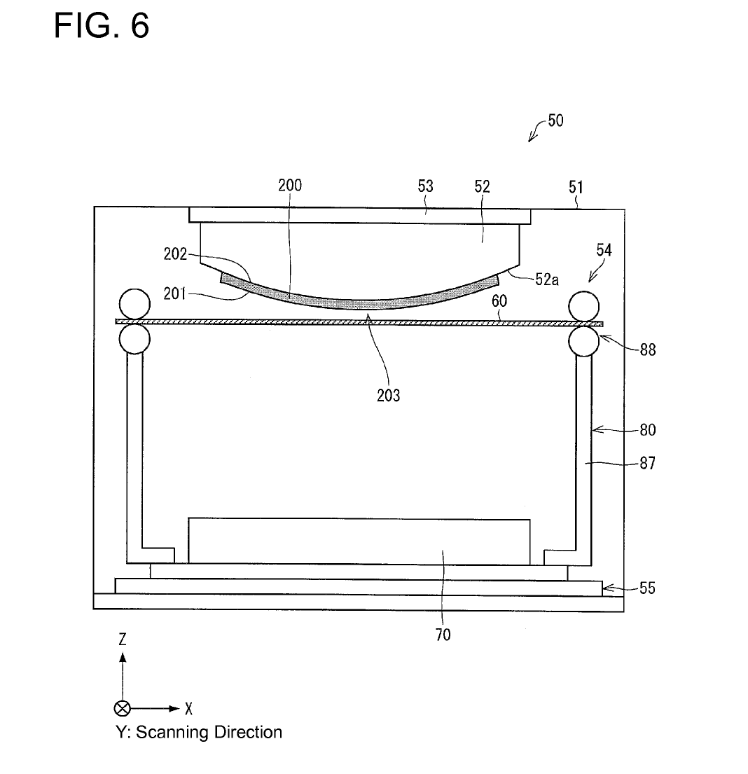

FIG. 6 is a schematic cross-sectional view of a configuration of main parts of the deposition device 50 according to this modification example.

As described above, the deposition device 50 according to FIG. 1 did not have a uniform gap (vertical distance) in the directional normal (Z axis direction/vertical direction) to the target substrate 200 and the deposition mask 60 along the direction perpendicular to the scanning direction, but there is no problem as long as this gap is as predicted beforehand, and changes of the gap during scanning or deterioration of repeating accuracy pose more of a problem than this.

As a countermeasure, as shown in FIG. 6, the mask unit 54 according to this modification example includes a mask holding member 87 in which the mask holding member 80 has a mask tension mechanism 88 instead of the mask holder 81, the mask tray 82, or the mask holder securing member 85.

As shown in FIG. 6, the deposition mask 60 and the evaporation source 70 according this modification example are provided with the mask holding member 87 that holds and secures the deposition mask 60 and the evaporation source 70 via the mask tension mechanism 88 (the same holder, for example), and the deposition mask 60 and the evaporation source 70 are held and secured relative to each other by being integrated with this mask holding member 87.

In this modification example, the deposition mask 60 has tension added thereto by the mask tension mechanism 88, which makes it so bending or stretching due to the weight thereof does not occur.

In the deposition device 50, the target substrate 200 is adhered to the substrate holding surface 52a of the target substrate 52 with an electrostatic chuck, and the deposition mask 60 is held horizontally by the mask tension mechanism 88, thereby maintaining a uniform gap between the target substrate 200 and the deposition mask 60 in the scanning direction.

In this manner, in the present embodiment, this gap can be uniformly maintained across the scanning direction, and changes in the gap or the like during scanning can be suppressed or prevented even if the deposition mask bends due to the weight thereof or becomes deformed due to heat from the evaporation source 70 caused by the size, materials, or the like of the deposition mask. Therefore, it is possible to improve deposition accuracy.

(Target Substrate 200 Holding Mechanism (Adhering Mechanism))

When the target substrate 200 is an ultra-large substrate as described above, a gap between the substrate holder 52 and the target substrate 200 causes marked occurrences of vibrations during scanning of the target substrate 200, and thus it is necessary to adhere the target substrate 200 to the substrate holder 52. Therefore, as described above, it is very efficacious for the substrate holder 52 to include an electrostatic chuck mechanism. The substrate holder 52 having an electrostatic chuck mechanism allows for the target substrate 200 to be easily and sturdily adhered to the substrate holder 52, and vibrations or shaking of the target substrate 200 during scanning will not occur.

Depending on the size of the target substrate 200, however, an arc-shaped fixing member, a bar-shaped fixing member, or the like may be used as the member for fixing the target substrate 200 to the substrate holder 52, as long as the target substrate 200 can be stably held and changes in the gap between the target substrate 200 and the deposition mask 60 during scanning can be suppressed or prevented, for example.

(Miscellaneous)

In FIG. 3, an example is shown in which the openings 61 in the deposition mask 60 and the emitting ports 71 of the evaporation source 70 are arrayed in one dimension (or namely, in a line). The present embodiment, however, is not limited to this, and the openings 61 in the deposition mask 60 and the emitting ports 71 of the evaporation source 70 may be arrayed two-dimensionally (or namely, in a plane).

The target substrate 200 used in the present embodiment may be a wiring substrate such as a TFT substrate, for example, or may be a passive substrate that will undergo vapor deposition but that does not have switching elements such as TFTs.

The deposited film may be an organic film, a metal film such as an electrode pattern, or an inorganic film.

The deposition device 50 according to the present embodiment can be suitably used as a manufacturing device for an organic EL display device and can be used for any method of manufacturing or any manufacturing device for depositing patterned films through vapor deposition.

### Embodiment 2

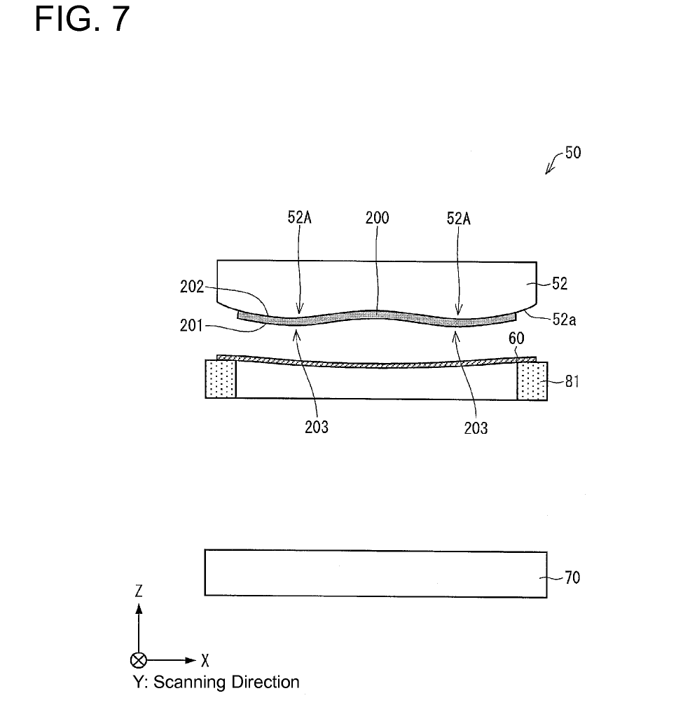

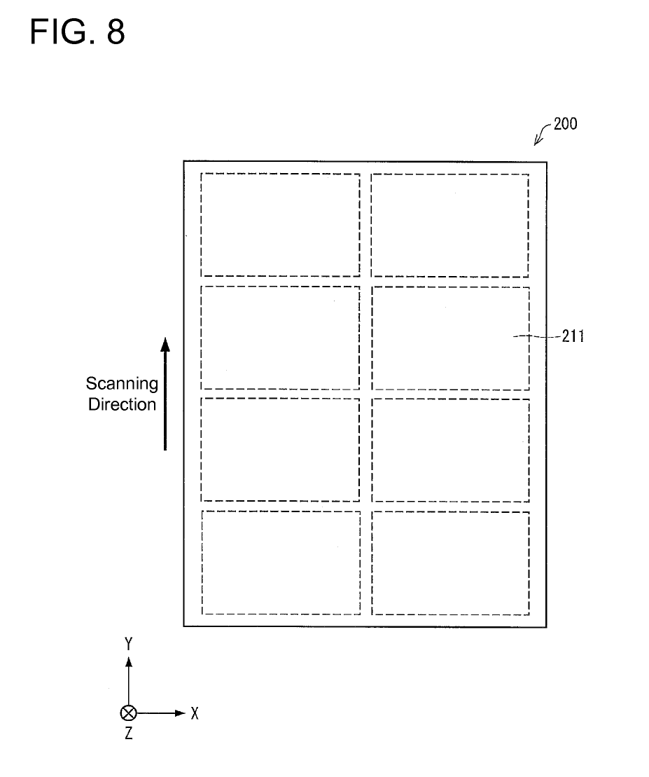

The present embodiment will be explained below with reference to FIGS. 7 to 9.

In the present embodiment, the differences with Embodiment 1 will primarily be explained, and constituting elements and functions that are the same as those used in Embodiment 1 will be given the same reference characters, and a repeat explanation thereof will be omitted.

FIG. 7 is a schematic cross-sectional view of the arrangement of various deposition elements around a substrate holder 52 in an evaporation apparatus 50 according to the present embodiment. FIG. 7 shows a cross section of the evaporation apparatus 50 according to the present embodiment when cut perpendicularly to the scanning direction. Elements other than the substrate holder 52, target substrate 200, deposition mask 60, mask holder 81, and evaporation source 70 have been omitted.

In Embodiment 1, an example was described in which the substrate holding surface 52a itself of the substrate holder 52 was curved, or in other words, there was only one curved portion on the substrate holder 52.

In the present embodiment, the substrate holding surface 52a of the substrate holder 52 has a plurality of curves 52A (two, in the example in FIG. 7) in the direction perpendicular to the scanning direction. Other constituting elements are the same as Embodiment 1, except for the arrangement of support members of a substrate mounting table 100, which is described later.

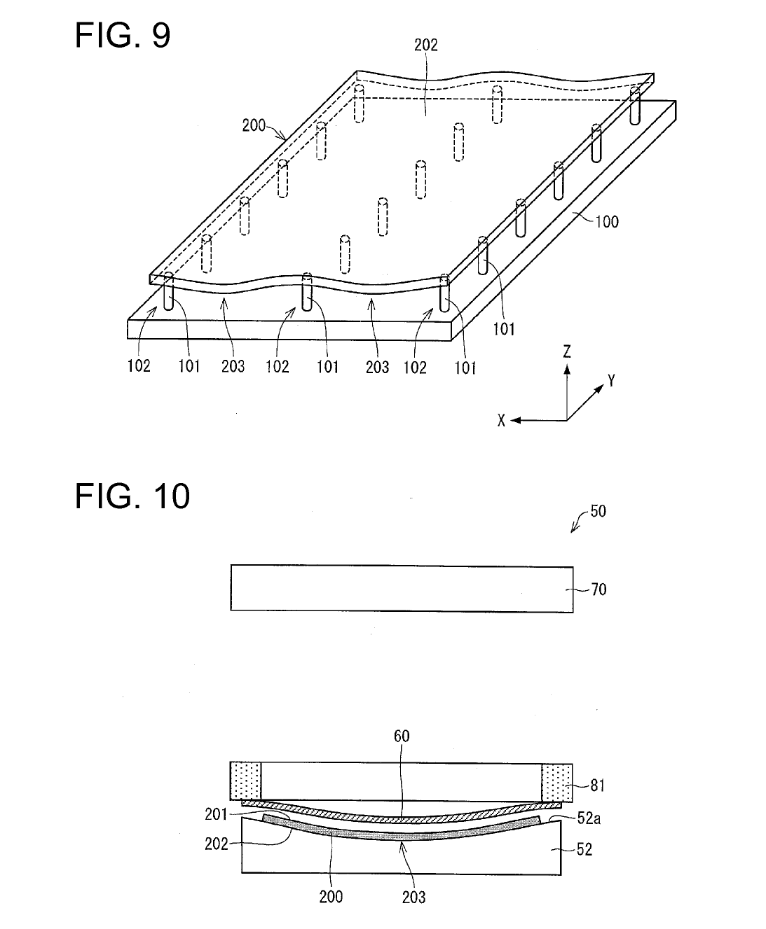

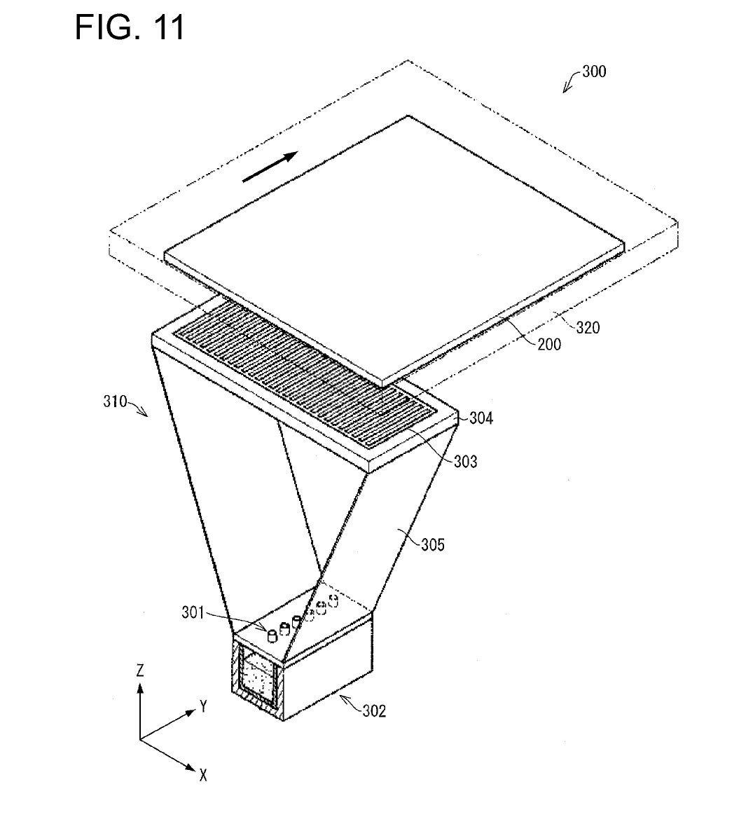

FIG. 8 is a plan view of the arrangement of panel areas 211 of the target substrate 200 used in the present embodiment, and FIG. 9 is a perspective view of a schematic configuration of the substrate mounting table 100 of the evaporation apparatus 50 according to the present embodiment. In the present embodiment, an example is described in which pins 101 are used as the support members.

The panel areas 211 of the target substrate 200 are each surrounded by a dotted line in FIG. 8, and the areas outside of these dotted lines are non-film deposition areas where film will not be deposited. Various types of patterns such as for TFT circuits and wiring lines are formed on the panels areas 211, which are all areas where film will be deposited, and the patterns for TFT substrate, wiring lines, and the like do not exist in the other areas outside these.

In the present embodiment, as shown in FIG. 9, the pins 101 are arranged in three columns with gaps therebetween, and respective pin columns 102 constituted of these pins 101 are arranged along both ends of the target substrate 200 parallel to the scanning direction and in the center of the scanning direction of the target substrate 200 along the scanning direction.

Thus, two downward protrusions 203 are formed in the direction perpendicular to the scanning direction on the target substrate 200 with the center of the scanning direction of the target substrate 200 therebetween.

As shown in FIG. 8, in the present embodiment, the panel areas 211 of the target substrate 200 are divided at the above-mentioned center, and the pins 101 are arranged on the non-film deposition areas surrounding the panel areas 211.

As described above, the order of the substrate delivery process is the same as Embodiment 1, except for the shape of the substrate holding surface 52a of the substrate holder 52 and the arrangement of the pins 101 being different. In the present embodiment, as in Embodiment 1, the target substrate 200 is adhered (secured) to the substrate holder 52 in a state in which a non-film deposition surface 202 is adhered to the substrate holding surface 52a, which is performed by this substrate holding surface 52a of the substrate holder 52 making slight contact with the target substrate 200 while the target substrate 200 is bent due to the weight thereof and the electrostatic chuck mechanism installed in the substrate holder 52 being turned ON.

As shown in FIG. 7, in the present embodiment, as in Embodiment 1, up deposition, in which vapor particles are emitted upwards, is performed by the target substrate 200 being disposed above the mask unit 54, and as described above, a film deposition surface 201 of the target substrate 200 is on the bottom when the non-film deposition surface 202 is adhered to the substrate holding surface 52a.

Therefore, the pins 101 being in the center of the target substrate 200 as described above causes the film deposition surface 201 to contact the pins 101 in the center of the target substrate 200. When the target substrate 200 is a wiring substrate such as a TFT substrate, there is a possibility that such contact could affect the subsequent vapor deposition process or the like, depending on the method of contact. Thus, it is preferable that the pins 101 contacting the panel areas 211 of the target substrate 200 be avoided.

Due to this, when the target substrate 200 is a large-sized TFT substrate as described above, for example, it is preferable that the panel areas 211 be divided at the substrate center, as shown in FIG. 8.

In the present embodiment, as described above, several pins 101 will be in the center of the target substrate 200. In the present embodiment, the arrangement itself of these pins 101 is not limited to the arrangement shown in FIG. 8. Essentially, in the present embodiment, as in Embodiment 1, the bending of the target substrate 200 due to the weight thereof should be able to correspond to the curved surface of the substrate holding surface 52a of the substrate holder 52.

<Effects>

According to the present embodiment, the substrate holding surface 52a of the substrate holder 52 has a plurality of curved portions in a direction perpendicular to the scanning direction, thereby reducing the bending of the target substrate 200 due to the weight thereof, as compared to Embodiment 1, and reducing the curvature of each curved portion. Thus, the present embodiment makes it possible to reduce the power of electrostatic chuck, for example. Due to this, the present embodiment allows for further simplification, reduction of weight, and the like of the substrate holder 52 using the electrostatic chuck, and enables a further improvement in productivity.

The further reduction in power of the electrostatic chuck reduces the charge of the target substrate 200, and makes it possible to more smoothly remove the target substrate 200 when the electrostatic chuck is turned OFF. Furthermore, by reducing the power of the electrostatic chuck, it is possible to further reduce the effects and damage to the TFTs when the target substrate 200 is a TFT substrate.

This type of simplification is useful for reducing the weight of the substrate holder 52, and the present embodiment can further reduce the costs of the device. The effects are particularly marked when the substrate holder 52 is provided above the mask unit, as described above, or when the substrate holder 52 physically scans (moves).

By reducing the curvature of each curved portion, it is possible to improve controllability of the gap between the target substrate 200 and the substrate holder 52 and controllability of the spread of pattern width of the deposited film (the scattering range of the vapor particles), thereby allowing for a further improvement in deposition accuracy.

In the present embodiment, as in Embodiment 1, the substrate holder 52 has a pre-defined shape that follows the bending of the target substrate 200 caused by the weight thereof and is able to withstand this weight, as described above, with respect to the target substrate 200, which is particularly affected by the weight thereof; therefore, the target substrate 200 can be stably secured to the substrate holder 52, thereby making it possible to reduce stress and warping of the target substrate 200 and to prevent vibrations or the like of the target substrate 200 during scanning. Furthermore, it is possible to stabilize the controllability (gap control) of the gap between the target substrate 200 and the deposition mask 60. Thus, it is possible to improve deposition accuracy and, due to the risk of damage to the target substrate 200 itself being reduced, possible to increase yield.

In the present embodiment, as in Embodiment 1, the size of the target substrate 200 has no particular limitations, but greater effects are exhibited when using a G6 or greater ultra-large substrate, or a thin substrate having a thickness of 1.0 mm or less, in particular.

### Modification Example

As in Embodiment 1, if the above-mentioned effects can be achieved, there are no particular limitations to the mechanism or shape of the respective parts of the evaporation apparatus 50 and the configurations besides the substrate holder 52, in particular. There are also no particular limitations to the structure of the evaporation source 70, the structure of the entire deposition device 50, and the like, for example. It is possible for modifications similar to Embodiment 1 to be performed.

Accordingly, the order of the substrate delivery process can be changed to be similar to Embodiment 1. Furthermore, support members other than the pins 101 may be used as the support members, in a manner similar to Embodiment 1.

In the present embodiment, an example was described in which the substrate holding surface 52a of the substrate 52 has two curves 52A in the direction perpendicular to the scanning direction, but the substrate holding surface 52a of the substrate holder 52 may have three or more curves 52A, or the target substrate 200 may have three or more protrusions 203 in the direction perpendicular to the scanning direction.

In this case, however, it is preferable that the curves 52A and the protrusions 203 be provided corresponding to the film deposition areas between the non-film deposition areas of the target substrate 200 in the direction perpendicular to the scanning direction.

### Embodiment 3

The present embodiment will be explained below with reference to FIG. 10.

In the present embodiment, the differences with Embodiment 1 will primarily be explained, and constituting elements and functions that are the same as those used in Embodiment 1 will be given the same reference characters, and a repeat explanation thereof will be omitted.

FIG. 10 is a schematic cross-sectional view of the arrangement of various deposition elements around a substrate holder 52 in an evaporation apparatus 50 according to the present embodiment. FIG. 10 is a cross section of the deposition device 50 according to the present embodiment when cut perpendicularly to the scanning direction, and elements other than the substrate holder 52, target substrate 200, deposition mask 60, mask holder 81, and evaporation source 70 are omitted in the drawing.

As described above, in Embodiment 1, an example is described in which the target substrate 200 is passed above the deposition mask 60 and the evaporation source 70 to perform up deposition, which is when the vapor particles are emitted upwards, on the film deposition surface 201 of the target substrate 200.

In the present embodiment, as shown in FIG. 10, the target substrate 200 is passed below the deposition mask 60 and the evaporation source 70 to perform down deposition, which is when the vapor particles are emitted downwards, on a film deposition surface 201 of the target substrate 200.

As shown in FIG. 10, in the present embodiment, the arrangement of the respective constituting elements are the same as in Embodiment 1, except for the substrate holder 52, the target substrate 200, the deposition mask 60, and the evaporation source 70 being provided from the bottom in this order, which is the opposite of FIG. 1.

As described above, however, the arrangement of the substrate holder 52, the target substrate 200, the deposition mask 60, and the evaporation source 70 is the opposite of the example shown in FIG. 1, and thus it is necessary for the evaporation source 70 to be disposed such that emitting ports 71 thereof face downwards, and for modifications to be made, such as changing the configuration of how the evaporation source 70 is held such that a mask unit 54 does not block the emitting ports 71. In this case, a mask holder securing member 85 may be a holder that has a frame unit supporting the evaporation source 70 at the ends thereof where the emitting ports are formed, or a shelf unit having protrusions that protrude across the scanning direction disposed in a direction perpendicular to the scanning direction, for example.

Although not shown, the member for securing the deposition mask 60 to the mask holder 61 can be an arc-shaped securing member, a bar-shaped securing member, or the like, for example. It is also possible to secure the deposition mask through welding. The present embodiment, however, is not limited to this, and in a similar manner to the securing of the evaporation source 70, the mask holder securing member 85 may have a frame unit supporting the deposition mask 60 at the ends thereof or have a shelf unit having protrusions that protrude across the scanning direction disposed in a direction perpendicular to the scanning direction, such that the opening area, which is constituted of openings 61, is not blocked, and the deposition mask 60 may be directly held by this mask holder securing member 85, for example.

In the present embodiment, as described above, the mask unit 54 is disposed above the substrate holder 52, and the deposition mask 60 is held in a state in which the deposition mask 60 is curved by the weight thereof.

Therefore, in the present embodiment, the substrate holding surface 52a of the substrate holder 52 has recessed curves that match the curves of the deposition mask 60.

Thus, in the present embodiment, the substrate holder 52 has a plano-concave lens shape with recesses on top, which is the opposite of Embodiment 1.

Due to this, in the present embodiment, as in Embodiment 1, the substrate holder 52 holds the target substrate 200 while being curved in the direction of the bending of the target substrate 200 caused by the weight thereof, but in the present embodiment, the substrate holding surface 52a of the substrate holder 52 has curved portions each having a curvature that is approximately the same (preferably exactly the same) as the respective curved portions of the open areas of the deposition mask 60, as described above, thereby making it possible to maintain a uniform gap (in the vertical direction) between the target substrate 200 and the deposition mask 60 across all deposition areas (areas where film will be deposited) on the target substrate 200 during scanning.

Therefore, the present embodiment makes it possible to maintain a uniform gap between the deposition mask 60 and the target substrate 200 even when the deposition mask 60 is curved, thereby allowing for an improvement in deposition accuracy.

The present embodiment also makes it unnecessary to exert unnecessary stress to hold the deposition mask horizontally (flat), thereby making it possible to improve the durability of the deposition mask. Thus, it is also possible to improve productivity.

In the present embodiment, the delivery of the target substrate 200 to the substrate holder 52 (the substrate delivery process) and the order thereof may be performed by any type of method.

In the present embodiment, the substrate holder 52 supports the target substrate 200 from below; thus, the target substrate 200, when mounted on the substrate holder 52, naturally bends due to the weight thereof until the curved surface of the substrate holder 52 and the non-film deposition surface 202 of the target substrate 200 contact each other. According to the present embodiment, the target substrate 200 naturally curves due to the weight thereof along the curved surface of the substrate holder 52 without any stress.

Therefore, in the present embodiment, it is not necessary to temporarily hold the target substrate 200 before the target substrate 200 is held by the substrate holder 52. Thus, the target substrate 200 may be directly transported or mounted on top of the substrate holder 52 by an arm or other unit (not shown) instead of being transported to the top of the substrate mounting table 100. Needless to say, the target substrate 200 may be mounted on the substrate holder 52 after curving due to the weight thereof by being suspended from above with a hanger or the like, for example.

In the present embodiment, due to the reasons described above, it is not necessary for the substrate holder 52 to have an electrostatic chuck mechanism. Therefore, the present embodiment makes it possible to simplify the holding mechanism of the target substrate 200, thereby allowing for a reduction in the costs of the device.

In the present embodiment, however, the substrate holder 52 does not need to have an electrostatic chuck mechanism. The substrate holder 52 having the electrostatic chuck mechanism makes it possible to prevent partial floating and the like of the target substrate 200 with respect to the substrate holder 52, and also makes it possible to prevent the target substrate 200 vibrating or shaking during the scanning of the target substrate 200. Therefore, it is possible to improve deposition accuracy.

<Summary>

According to one aspect of the present invention, an evaporation apparatus for forming a thin film having prescribed patterns on a substrate includes: a mask unit including a deposition mask that has at least one opening and faces the substrate, and an evaporation source, the mask unit being secured in a position relative to the deposition mask; a substrate holder for holding the substrate at a gap from the deposition mask; and a moving mechanism that moves one of the a mask unit and the substrate relative to the other of the a mask unit and the substrate, wherein a width of the deposition mask in a scanning direction of the moving mechanism is less than a width of the substrate in the scanning direction, and wherein a substrate holding surface of the substrate holder has at least one curved portion along the scanning direction, the curved portion being within a range of a bend in the substrate caused by a weight thereof and curving in a direction perpendicular to the scanning direction of the moving mechanism.

In order to withstand the weight of the target substrate and hold the target substrate horizontally, it is necessary to have a markedly durable electrostatic chuck, which increases overall costs, and also puts a burden on the deposition device mechanism and affects the costs of the device due to the large size of the electrostatic chuck. Furthermore, the effects of positional deviations and warping of the target substrate while using the electrostatic chuck are significant, and this causes a drop in productivity such as by a reduction in deposition accuracy or, at worst, the breaking of the target substrate.

According to the present invention, however, the substrate holding surface of the substrate holder has a curved portion that curves within a range of bending of the target substrate caused by the weight thereof, thereby making it unnecessary to hold the target substrate horizontally to withstand the weight thereof, and allowing for a reduction in stress and warping of the target substrate and the stable holding thereof.

Thus, it is possible to improve deposition accuracy and, due to the danger of damage to the target substrate itself being reduced, possible to increase yield and productivity.

According to the respective configurations above, it is not necessary to have a markedly strong large-sized electrostatic chuck, as would be required to withstand the weight of the target substrate and hold the target substrate horizontally; therefore, it is possible to reduce the costs of the device and the weight of the substrate holder. The effects are particularly salient when the substrate holder is provided above the mask unit, or when the substrate holder is moved. When the substrate holder has an electrostatic chuck mechanism, for example, it is possible to reduce the power of the electrostatic chuck and to reduce the costs of the device due to this.

The curved portion of the substrate holder curves along the scanning direction in a direction perpendicular to the scanning direction, and scanning is performing along the axis direction of the curved portion, thereby making the substrate holding surface of the substrate holder maintain a uniform curved shape along the scanning direction. Due to this, the gap between the target substrate and the deposition mask can be uniformly maintained along the scanning direction during scanning.

A second aspect of the evaporation apparatus of the present invention is the first aspect, wherein the curved portion of the substrate holding surface is formed such that the substrate has at least one downward protrusion within a range of a bend in whichever one of the substrate and the deposition mask is in a top position.

In any case, as described above, the substrate holding surface of the substrate holder has a curved portion that curves within a range of bending of the target substrate caused by the weight thereof, thereby making it unnecessary to hold the target substrate horizontally to withstand the weight thereof, and allowing for a reduction in stress and warping of the target substrate and the stable holding thereof. This also makes it possible to stably maintain the gap between the target substrate and the deposition mask in the scanning direction.

A third aspect of the evaporation apparatus of the present invention is the first aspect or the second aspect, wherein the substrate is disposed above the a mask unit, and wherein the curved portion of the substrate holder is formed to be within the range of the bend of the substrate caused by the weight thereof.

With this configuration, if the target substrate is disposed above the mask unit, the curved portion of the substrate holder will match the bending of the target substrate caused by the weight thereof, thereby allowing for stress and warping of the target substrate to be reduced (or eliminated), and making it possible to stably hold the target substrate. Furthermore, the target substrate will not vibrate or shake during scanning. Due to this, it is possible to improve deposition accuracy, and the risk of the target substrate itself being damaged is also reduced, thereby allowing for a further improvement in yield.

In particular, when the substrate holder has an electrostatic chuck mechanism, it is possible to have a further reduction in the power of the electrostatic chuck and to reduce the costs of the device due to this. When using an electrostatic chuck on the target substrate, the gap between the target substrate and the substrate holding surface of the substrate holder changes very little, thereby allowing for the electrostatic chuck to be used with ease.

A fourth aspect of the evaporation apparatus of the present invention is any one of the first to third aspects, wherein the substrate holder has an electrostatic chuck mechanism.

Due to the substrate holder having the electrostatic chuck mechanism, the target substrate can be sturdily and stably adhered to the substrate holder with ease, and there will be no vibrating or shaking of the target substrate during scanning.

In particular, when using a large-sized substrate as the target substrate, a gap between the substrate holder and the target substrate leads to a marked occurrence of vibrations of the target substrate during scanning, and it is necessary to adhere the substrate holder and the target substrate to each other. Due to this, it is very efficacious for the substrate holder to be provided with an electrostatic chuck mechanism.

According to the present embodiment, as described above, even if the substrate holder has the electrostatic chuck mechanism, it is not necessary to have a very durable large-sized electrostatic chuck as would be necessary to withstand the weight of the target substrate and hold the target substrate horizontally. This makes it possible to reduce the power of the electrostatic chuck, thereby reducing the costs of the device. When using an electrostatic chuck on the target substrate, the gap between the target substrate and the substrate holding surface of the substrate holder changes very little, thereby allowing for the electrostatic chuck to be used with ease.

When using the electrostatic chuck in this manner, it is possible to reduce the power of the electrostatic chuck more than in conventional configurations; therefore, it is possible to reduce the charge of the target substrate and to smoothly remove the target substrate when the electrostatic chuck is turned OFF.

By reducing the power of the electrostatic chuck, it is possible to reduce the effect on the TFTs or the damage thereof when the target substrate is a TFT substrate, for example.

A fifth aspect of the evaporation apparatus of the present invention is the first to forth aspects, further including a substrate supporting member that temporary holds the substrate before the substrate is held by the substrate holder, wherein the substrate supporting member includes a plurality of support members that support the substrate continuously or with gaps therebetween across the scanning direction at locations on the substrate corresponding to both ends of the curved portion of the substrate holder, and wherein the substrate is delivered from the support members to the substrate holder in a state where the bend in the substrate caused by the weight thereof occurs due to being supported by the support members.

In this manner, before the target substrate is held by the substrate holder, the target substrate is supported by the support members, thereby allowing the target substrate to bend due to the weight thereof in a shape corresponding to the arrangement of the support members beforehand. Delivery of the target substrate in this state from the support members to the substrate holder makes it possible to adhere the target substrate to the substrate holder with ease and without stress or warping of the target substrate.

Furthermore, as described above, when the target substrate is allowed to bend due to the weight thereof in a shape corresponding to the arrangement of the support members while being supported by these support members, if the support members contact the deposition areas of the target substrate, then there is a possibility that this could affect the subsequent deposition process or the like if the target substrate is a wiring substrate such as a TFT substrate. Thus, it is preferable that the support members contacting the deposition areas of the target substrate be avoided.

Therefore, a sixth aspect of the evaporation apparatus of the present invention is the fifth aspect, wherein the curved portion of the substrate holder corresponds to a film deposition area between non-film deposition areas on the substrate in the direction perpendicular to the scanning direction.

A seventh aspect of the evaporation apparatus of the present invention is any one of the first to sixth aspects, wherein one of the curved portion is provided in the direction perpendicular to the scanning direction. An eighth aspect of the evaporation apparatus of the present invention is any one of the first to sixth aspects, wherein a plurality of the curved portions are provided in the direction perpendicular to the scanning direction.

When one curved portion is disposed in the direction perpendicular to the scanning direction, it is possible to simplify the configuration of the substrate holder, as compared to if a plurality of the curved portions were provided in the direction perpendicular to the scanning direction. Furthermore, if temporarily supporting the target substrate with support members when the one curved portion is provided in the direction perpendicular to the scanning direction, it is possible to simplify the arrangement of the support members and to reduce the number of support members, as compared to if a plurality of the curved portions were provided in the direction perpendicular to the scanning direction.

On the other hand, if a plurality of the curved portions are provided in the direction perpendicular to the scanning direction, then the curvature of each of the curved portions can be reduced, as compared to if only one curved portion were disposed in the direction perpendicular to the scanning direction.

This makes it possible to improve the controllability of the spread of the pattern width of the deposited film (the scattering range of the vapor particles) and the controllability of the gap between the target substrate and the substrate holder, which allows for a further improvement in deposition accuracy.

By reducing the curvature of each of the curved portions, it is possible to reduce the power of the electrostatic chuck, for example. Thus, when the substrate holder has an electrostatic chuck mechanism, the substrate holder having the electrostatic chuck mechanism can be simplified and the weight thereof and the like can be reduced, as compared to if only one curved portion were provided in the direction perpendicular to the scanning direction, thereby allowing for a further improvement in productivity and reduction in costs of the device. The further reduction of power of the electrostatic chuck reduces the charge of the target substrate, and makes it possible to more smoothly remove the target substrate when the electrostatic chuck is turned OFF. Furthermore, by reducing the power of the electrostatic chuck, it is possible to further reduce the effects and damage to the TFTs when the target substrate is a TFT substrate.

A ninth aspect of the evaporation apparatus of the present invention is any one of the first to eighth aspects, wherein a uniform gap between the substrate and the deposition mask is maintained in a direction normal thereto along the scanning direction during scanning, and wherein a size and a shape of the opening in the deposition mask are determined in accordance with the uniform gap between the substrate and the deposition mask in the direction normal thereto perpendicular to the scanning direction such that a film of a desired thickness is deposited in the direction perpendicular to the scanning direction.

In the deposition device, the substrate holder having the curved portion as described above makes it so the gap between the target substrate and the deposition mask is not uniform along the direction perpendicular to the scanning direction. If the distance normal to the gap between the target substrate and the deposition mask in the scanning direction is uniformly maintained, however, then a film of a desired thickness can be deposited on a desired area by configuring the size and shape of the openings in the deposition mask such that the film of the desired thickness is deposited at the desired areas in accordance with this distance.

A tenth aspect of the evaporation apparatus of the present invention is any one of the first to ninth aspects, wherein the a mask unit is disposed below the substrate holder, wherein the a mask unit further includes a tension mechanism that exerts tension on the deposition mask, and wherein the tension mechanism maintains a uniform gap between the substrate and the deposition mask in a direction normal thereto along the scanning direction.

With this configuration, even if the deposition mask bends due to the weight thereof or is deformed by heat from the evaporation source due to the size, materials, or the like of the deposition mask, the gap will be uniformly maintained across the scanning direction, and it will be possible to suppress or prevent changes in the gap or the like during scanning. Therefore, it is possible to improve deposition accuracy.

An eleventh aspect of the evaporation apparatus of the present invention is the first or second aspect, wherein the a mask unit is disposed above the substrate holder, wherein the deposition mask is maintained in a state where the deposition mask has a curved portion due to a weight thereof, and wherein the curved portion of the substrate holder is a recess within a range of the curved portion of the mask unit in the opening of the deposition mask.

With this configuration, even if the deposition mask is curved as described above, the gap between the target substrate and the deposition mask (the distance in the direction normal to the gap) can be uniformly maintained across all deposition areas of the target substrate during scanning. Therefore, it is possible to improve deposition accuracy.

Furthermore, with this configuration, it is not necessary for unneeded stress to be exerted in order to make the deposition mask horizontal (flat), thereby allowing for an improvement in the durability of the deposition mask. Thus, it is also possible to improve productivity.

The present invention is not limited to the embodiments described above, and various modifications can be made without departing from the scope of the claims. Therefore, embodiments obtained by appropriately combining the techniques disclosed in different embodiments are included in the technical scope of the present invention.

### INDUSTRIAL APPLICABILITY

The evaporation apparatus according to the present invention can be suitably applied to manufacturing devices for organic EL display devices, manufacturing devices that deposit patterned films through vapor deposition, and in particular, to large-sized substrates on which film deposition will be performed.

### DESCRIPTION OF REFERENCE CHARACTERS

50 evaporation apparatus
51 vacuum chamber
52 substrate holder
52a substrate holding surface
52A curve
53 substrate moving mechanism
54 mask unit
55 mask unit moving mechanism
60 deposition mask
60a long side
60b short side
61 mask holder
61 opening
61a short side
61b long side
70 evaporation source
71 emitting port
80 mask holding member
81 mask holder
81a opening
85 mask holder securing member
87 mask holding member
88 mask tension mechanism
100 substrate mounting table (target substrate holding unit)
101 pin (support member)
102 pin column
200 target substrate
200a short side
200b long side
201 film deposition surface
202 non-film deposition surface
203 protrusion
211 panel area

1. An evaporation apparatus for forming a thin film having prescribed patterns on a substrate, the evaporation apparatus comprising:
an evaporation unit including a deposition mask that has at least one opening and faces the substrate, and an evaporation source, said evaporation unit being secured in a position relative to the deposition mask;
a substrate holder for holding the substrate at a gap from the deposition mask; and
a moving mechanism that moves one of the evaporation unit and the substrate relative to the other of the evaporation unit and the substrate,
wherein a width of the deposition mask in a scanning direction of the moving mechanism is less than a width of the substrate in said scanning direction, and
wherein a substrate holding surface of the substrate holder has at least one curved portion along the scanning direction, said curved portion being within a range of a bend in the substrate caused by a weight thereof and curving in a direction perpendicular to the scanning direction of the moving mechanism.

2. The evaporation apparatus according to claim 1, wherein the curved portion of the substrate holding surface is formed such that the substrate has at least one downward protrusion within a range of a bend in whichever one of the substrate and the deposition mask is in a top position.

3. The evaporation apparatus according to claim 1,
wherein the substrate is disposed above the evaporation unit, and
wherein the curved portion of the substrate holder is formed beforehand to be within the range of the bend of the substrate caused by the weight thereof.

4. The evaporation apparatus according to claim 1, wherein the substrate holder has an electrostatic chuck mechanism.

5. The evaporation apparatus according to claim 1, further comprising:
a substrate supporting member that temporary holds the substrate before said substrate is held by the substrate holder,
wherein the substrate supporting member includes a plurality of support members that support the substrate continuously or with gaps therebetween across the scanning direction at locations on the substrate corresponding to both ends of the curved portion of the substrate holder, and
wherein the substrate is delivered from the support members to the substrate holder in a state where the bend in the substrate caused by the weight thereof occurs due to being supported by the support members.

6. The evaporation apparatus according to claim 5, wherein the curved portion of the substrate holder corresponds to a film deposition area between non-film deposition areas on the substrate in the direction perpendicular to the scanning direction.

7. The evaporation apparatus according to claim 1, wherein one of said curved portion is provided in the direction perpendicular to the scanning direction.

8. The evaporation apparatus according to claim 1, wherein a plurality of said curved portions are provided in the direction perpendicular to the scanning direction.

9. The evaporation apparatus according to claim 1,
wherein a uniform gap between the substrate and the deposition mask is maintained in a direction normal thereto along the scanning direction during scanning, and
wherein a size and a shape of the opening in the deposition mask are determined in accordance with said uniform gap between the substrate and the deposition mask in the direction normal thereto such that a film of a desired thickness is deposited in the direction perpendicular to the scanning direction.

10. The evaporation apparatus according to claim 1,
wherein the evaporation unit is disposed below the substrate holder,
wherein the evaporation unit further comprises a tension mechanism that exerts tension on the deposition mask, and
wherein the tension mechanism maintains a uniform gap between the substrate and the deposition mask in a direction normal thereto along the scanning direction.

11. The evaporation apparatus according to claim 1,
wherein the evaporation unit is disposed above the substrate holder,
wherein the deposition mask is maintained in a state where the deposition mask has a curved portion due to a weight thereof, and
wherein the curved portion of the substrate holder is a recess within a range of the curved portion of the evaporation unit in the opening of the deposition mask.
